(19) United States
(12) Patent Application Publication
(10) Pub. No.: US 2012/0250262 A1
(43) Pub. Date: Oct. 4, 2012

(54) ELECTRONIC ASSEMBLY COMPRISING A DRAWER AND A COMPARTMENT FOR RECEIVING BOARDS

(75) Inventors: Gregory Faucheux, Couzon au Mont J'or (FR); Christian Ruque, Corbas (FR)

(73) Assignee: ALSTOM TRANSPORT SA, Levallois-Perret (FR)

(21) Appl. No.: 13/245,844

(22) Filed: Sep. 26, 2011

(30) Foreign Application Priority Data
Sep. 27, 2010 (FR) 10 57773

(51) Int. Cl. H05K 7/14; H01R 43/26; H05K 9/00

(52) U.S. Cl. 361/725; 29/825

(57) ABSTRACT

An electronic assembly comprising: a drawer comprising sites for receiving removable boards; a compartment comprising a drawer holder and a connector holder, the drawer being able to be removably inserted into the drawer holder; a first compartment connector part associated with each board site, fastened on the connector holder and provided to be plugged in with a second compartment connector part fastened on a board due to the insertion of the drawer equipped with the board into the drawer holder; and at least one electromagnetic protection screen provided to be adjacent to a first compartment connector part and able to produce an electrical connection between the drawer holder or the connector holder and a board arranged in the site associated with the first compartment connector part when the drawer is inserted into the compartment.

### CROSS REFERENCE TO RELATED APPLICATION

This application claims priority to French Patent Application No. 10 57773, filed 27 Sep. 2010, the disclosure of which is incorporated, in its entirety, by this reference.

### BACKGROUND

Patents EP 0 785 706 and EP 1 732 374 disclose such electronic assemblies with automatic pinning and unpinning. In these electronic assemblies, the compartment connectors are arranged at the bottom of the compartment and their connection is done blindly during the insertion of the drawer equipped with boards in the compartment.

The connectors used for these blind connections have satisfactory immunity relative to electromagnetic disruptions.

Nevertheless, due to the increasing use of new, more demanding types of connections, in particular Ethernet-type network connections, it is necessary to increase the level of immunity against electromagnetic disruptions, or “electromagnetic shielding level.”

### SUMMARY

The present invention relates to an electronic assembly, of the type comprising:

a drawer comprising sites for receiving boards that can be removably inserted into the drawer;

a compartment comprising a drawer holder having an insertion opening at the front of the drawer holder and a connector holder at the rear of the drawer holder, the drawer being able to be removably inserted into the drawer holder from front to back, in a longitudinal direction;

a first compartment connector portion associated with each board site, fastened on the connector holder and provided to be plugged in with a second compartment connector part fastened on a board due to the insertion of the drawer equipped with the board into the drawer holder.

Such an electronic assembly makes it possible to connect, disconnect, respectively, the male and female parts of the compartment connectors due to the insertion of the drawer equipped with boards in the compartment, or the removal thereof from the compartment, respectively. Such an electronic assembly is generally designated as having “automatic pinning and unpinning.” The terms “pinning” and “unpinning” designate the connection and disconnection, respectively, of the male and female parts of the connector.

One aim of the invention is to propose an electronic assembly with automatic pinning and unpinning having an improved immunity to electromagnetic disruptions.

To that end, this invention proposes an electronic assembly of the aforementioned type, characterized in that it comprises at least one electromagnetic protection screen provided to be adjacent to a first compartment connector part and able to produce an electrical connection between the drawer holder or the connector holder and a board arranged in the site associated with the first compartment connector part when the drawer is inserted into the compartment.

According to other embodiments, the electronic assembly comprises one or more of the following features, considered alone or according to all technically possible combinations:

the screen extends backward and/or forward from the connector holder relative to the longitudinal direction;

the screen is configured to physically separate two first adjacent compartment connector parts by defining a separating partition between them in the bottom of the compartment;

the screen comprises at least one stationary part fastened on the connector holder;

the screen comprises at least one mobile part fastened on a board or on the drawer;

the stationary part and the mobile part are complementary and connect electrically upon insertion of the drawer equipped with the boards into the compartment to form the screen;

an electromagnetic continuity seal arranged so that the stationary part and the mobile part connect electrically via said electromagnetic continuity seal;

the electromagnetic continuity seal is arranged on the stationary part or on the mobile part;

a screen comprises a piece comprising a protective portion provided to extend along a compartment connector and a portion for fastening the protective portion, forming an angle with the protective portion, in particular an angle of about 90°;

the protective portion and the fastening portion define a “T” or “L” shape;

a screen comprising a substantially planar plate; and

at least one board that can be inserted into a site of the drawer and comprising a second compartment connector part complementary to the first compartment connector part associated with the site.

The invention also relates to a board for producing an electronic assembly as defined above, comprising a second compartment connector part complementary with a first compartment connector part associated with a site of the drawer.

In one embodiment, the board comprises at least one mobile electromagnetic protective screen part adjacent to the second compartment connector part.

The invention also relates to the use of an electronic assembly as defined above to connect a board.

### BRIEF DESCRIPTION OF THE DRAWINGS

The invention and its advantages will be better understood upon reading the following description, provided solely as an example, and done in reference to the appended drawings, in which:

FIGS. 1 and 2 are cross-sectional side and top views, respectively, of an electronic assembly according to the invention, in an exploded configuration;

FIG. 3 is a cross-sectional top view of the electronic assembly of FIGS. 1 and 2 in the assembled configuration;

FIGS. 4 and 5 are cross-sectional top views of an electronic assembly according to a second embodiment, in an exploded configuration and an assembled configuration, respectively.

### DETAILED DESCRIPTION OF EXEMPLARY EMBODIMENTS

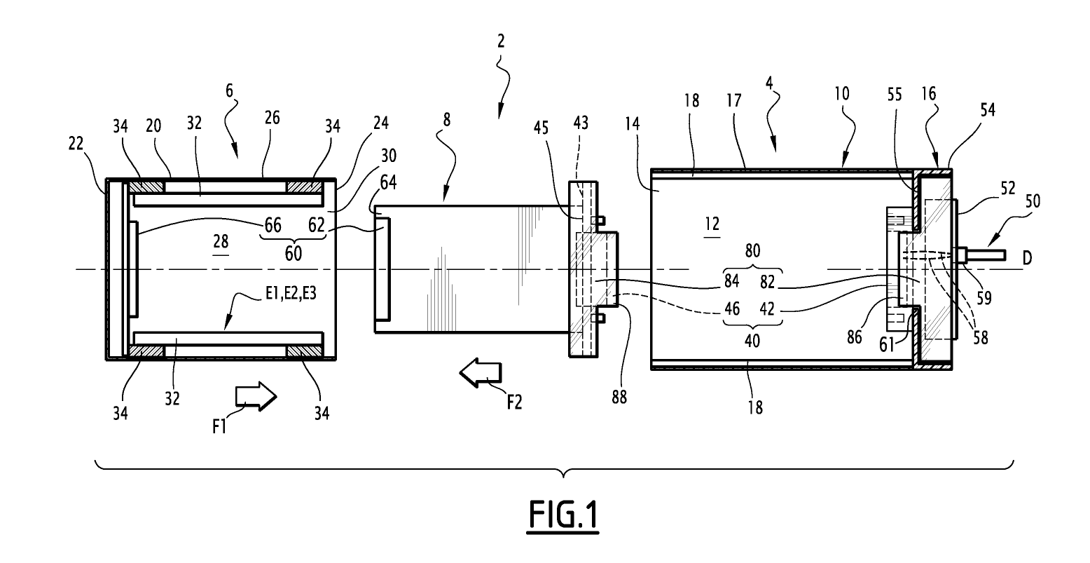

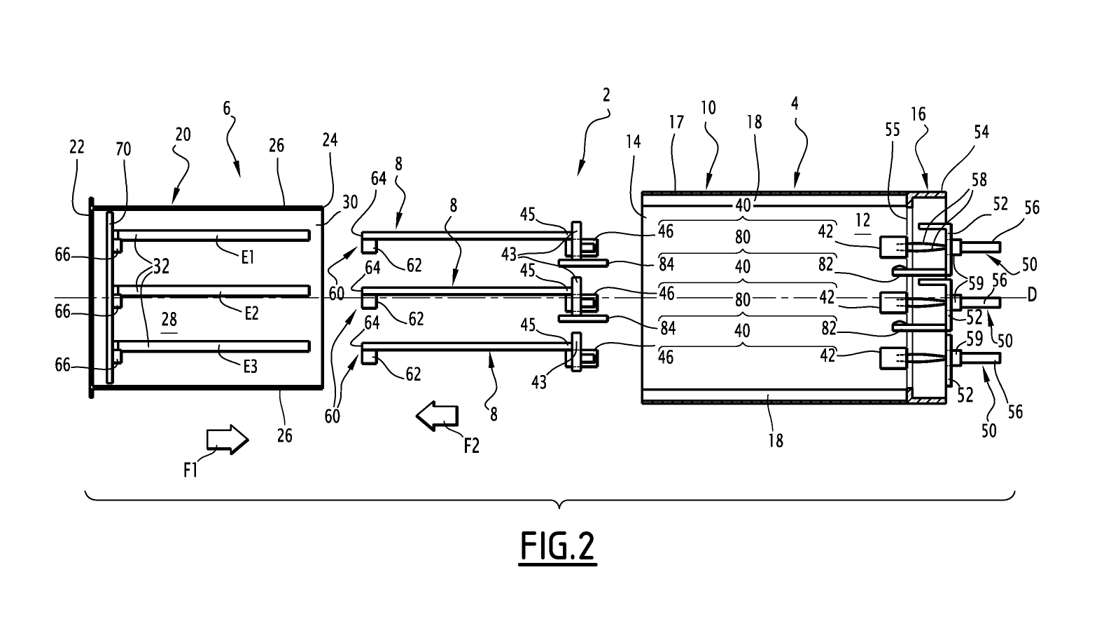

The electronic assembly 2 illustrated in FIGS. 1 and 2 comprises a compartment 4, a drawer 6 that can be removably inserted into the compartment 4 and boards 8 that can be removably inserted in the drawer 6, and hereafter called daughter boards 8.

Three daughter boards 8 are illustrated in FIG. 2, only one being visible in FIG. 1. The electronic assembly 2 can comprise a different number of boards, in particular more than three.

The compartment 4 is for example a compartment of an electrical cabinet or an electronics bay comprising a plurality of compartments. The electrical cabinet or electronics bay is arranged in a building, vehicle, in particular a rail vehicle, or on a machine tool.

The drawer 6 can be inserted in the compartment 4 in a longitudinal insertion direction D.

In the rest of the description, the terms “front” and “back” are used in reference to the insertion of the drawer 6 into the compartment 4 in longitudinal direction D, from front to back along arrow F1 of FIGS. 1 and 2, and its removal in direction D, from back to front.

The compartment 4 comprises a drawer holder 10 delimiting a housing 12 for receiving the drawer 6 and having a front opening 14 for inserting the drawer 6 into the housing 12 in the longitudinal direction D and a connector holder 16 fastened to the back of the drawer holder 10 and closing the back end of the housing 12.

The drawer holder 10 comprises an outer frame 17 delimiting the housing 12 and inner drawer guides 18, arranged inside the outer frame 17 for sliding insertion of the drawer 6 into the compartment 4.

The drawer 6 comprises an enclosure 20 having a front surface 22, a back surface 24 and side surfaces 26 delimiting a space 28 for receiving the daughter boards 8. The back surface 24 is provided with a back opening 30 for the insertion of the daughter boards 8 in the drawer 6. The drawer 6 comprises a respective site E1, E2, E3 (FIG. 2) for each daughter board 8.

Each daughter board 8 can be inserted into the drawer 6 at its site E1, E2, E3 in the longitudinal direction from back to front, through the rear surface 24 of the drawer 6, along Arrow F2 of FIGS. 1 and 2.

The drawer 6 comprises, for each daughter board 8, a pair of longitudinal guideways 32 fastened on opposite side surfaces 26 to receive two opposite side edges (FIG. 1) of the daughter board 8, and defining a site E1, E2, E3. The guideways 32 are spaced transversely to define the sites E1, E2, E3 and connected to the enclosure 20 by transverse beams 34 (FIG. 1).

The insertion of the daughter boards 8 in the drawer 6 and the drawer 6 into the compartment 4 ensures the connection of the electrical masses of the daughter boards 8 to the electrical mass of the electronic assembly 2. To that end, the guideways 32, the beams 34 and the enclosure 20 are metal, and the guides 18 and the outer frame 17 are metal, so as to provide an electrical connection for electrical grounding between the daughter boards 8 and the outer frame 17, the latter constituting or being connected to the electrical mass of the electronic assembly 2.

The electronic assembly 2 comprises compartment connectors 40. Each compartment connector 40 comprises a first compartment connector 40 part 42 fastened on the connector holder 16 and a second connector compartment 40 part 46 fastened on a back edge 45 of a daughter board 8.

The first compartment connector 40 parts 42 are therefore arranged in the bottom of the compartment 4.

The second compartment connector 40 parts 46 are for example fastened on a metal façade 43 fastened on a back edge 45 of each daughter board 8.

The first 42 and second 46 parts of each compartment connector 40 are complementary. One of the first 42 and second 46 compartment connector 40 parts is a female part and the other is a male part.

The first 42 and second 46 parts of each compartment connector 40 are arranged so as to connect by plugging one into the other during insertion of the drawer 6 equipped with the daughter boards 8 in the compartment 4.

Conversely, the removal of the drawer 6 causes the first 42 and second 46 compartment connector 40 parts to separate.

The electronic assembly therefore has automatic pinning and unpinning.

The electronic assembly 2 comprises a cable 50 associated with each compartment connector 40 and connected to the second part 46 of said compartment connector. Each cable 50 is shielded and fastened on the connector holder 16 via a mounting and take-up shielding clip 52.

Each clip 52 is fastened on the back of the connector holder 16. More specifically, each clip 52 is fastened on an edge 54 of the connector holder 16 extending toward the back from a plate 55 of the connector holder 16 closing at the back of the housing 12 and carrying the first compartment connector 40 parts 42. Each clip 52 is longitudinally spaced from the plate 55 of the connector holder 16.

Each cable 50 comprises a shielding sheath 56 and conductors 58 surrounded by the sheath 56. The sheath 56 is fastened and connected to the clip 52 via a shielding take-up fastener 59. The sheath 56 is interrupted at the clip 52. The conductors 58 extend outside the sheath 56 between the clip 52 and the plate 55 of the connector holder 16, and are connected to the first part 42 of the associated compartment connector 40 through an orifice 61 of the plate 55.

Each clip 52 is metal and electrically connected to the connector holder 16. The connector holder 16 is metal and connected to the frame 17. In this way, each clip 52 connects the sheath 56 of the associated cable 50 to the electrical mass of the electronic assembly 2.

The electronic assembly 2 comprises drawer connectors 60. Each drawer connector 60 comprises a first connector part 62 fastened on a front edge 64 of a daughter board 8 and a second connector part 66 fastened in the space 28 of the drawer 6.

The first 62 and second 66 parts of each drawer connector 50 are complementary. One of the first 62 and second 66 drawer connector parts 60 is a female part and the other is a male part.

The first 62 and second 66 parts of each drawer connector 60 are arranged so as to connect by plugging one into the other during insertion of the corresponding daughter board 8 in the drawer 6 along arrow F2 in FIGS. 1 and 2.

The electronic assembly 2 comprises a board 70, hereafter called motherboard 70, fastened inside the drawer 6 near the front surface 22 of the drawer 6 opposite the back surface 24 provided with the back opening 30 for inserting daughter boards 8. The second drawer connector 60 parts 66 are fastened on the motherboard 70. The daughter boards 8 inserted into the drawer 6 are interconnected via the motherboard 70 (FIG. 2).

The electronic assembly 2 comprises means for electromagnetic protection of the compartment connectors 40.

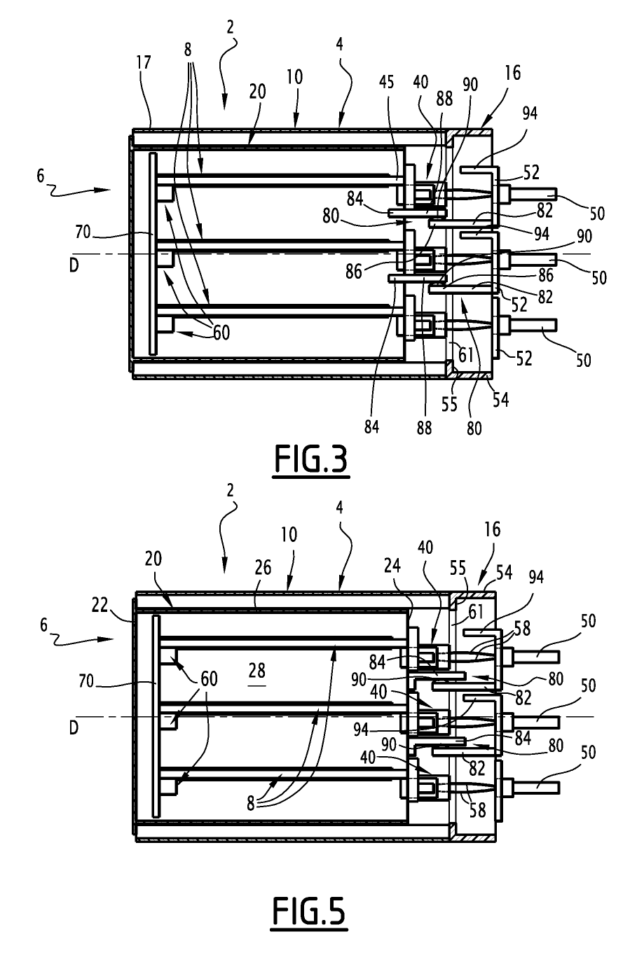

More specifically, the electronic assembly 2 comprises electromagnetic protection screens 80. Each screen 80 is arranged near a compartment connector 40 and extends along the latter to protect it from electromagnetic disruptions when the drawer 6 equipped with the boards 8 is inserted in the compartment 4 (FIG. 3).

Each screen 80 is electrically conductive and is electrically connected, on the one hand, to the drawer holder 10 and/or the connector holder 16 and, on the other hand, to a daughter board 8 and/or the drawer 6, when the drawer 6 equipped with the daughter boards 8 is inserted into the compartment 6. Each screen 80 consequently produces an electrical connection between said elements.

The daughter boards 8 are arranged side by side and spaced apart transversely. Each screen 80 extends in the longitudinal direction D between two connectors of the compartment 40 when the drawer equipped with the daughter boards 8 is inserted into the compartment.

The electronic assembly 2 here comprises two screens 80 each extending in one of the two intervals between the three daughter boards 8, respectively.

Each screen 80 comprises a stationary part 82 fastened on the connector holder 16 and a mobile part 84 fastened on a daughter board 8, which are complementary. The stationary part 82 and the mobile part 84 are electrically conductive and are electrically connected when the drawer 6 equipped with the daughter boards 8 is inserted into the compartment 4 (FIG. 3).

The stationary part 82 of each screen 80 assumes the form of a substantially planar thin metal plate. As shown, it extends toward the back from the plate 55 of the connector holder 16 to the vicinity of or into contact with a clip 52, and has a front extension 86 extending toward the front through the orifice 61 of the plate 55 of the connector holder 16, in the housing 12.

The mobile part 84 of each partition 80 assumes the form of a substantially planar thin metal plate. It extends along the back edge 44 of the daughter board 8 and has a rear extension 88 extending toward the back from the back edge of the daughter board 8. In the illustrated example, the mobile part 84 is fastened on the side of the metal façade 43 of the daughter board 8 (FIGS. 2 and 3).

The stationary part 82 and the mobile part 84 connect to each other via their extensions 86, 88 coming into contact during insertion of the drawer 6 into the compartment 6.

The stationary 82 and mobile 84 parts can come into direct contact.

Optionally, as illustrated in FIGS. 2 and 3, an electromagnetic continuity (EMC) seal 90 is arranged so that the stationary 82 and mobile 84 parts come into electrical contact via said seal 90. The seal is arranged on the stationary part 82. Alternatively, the seal 90 is arranged on the mobile part 84.

Alternatively, the EMC seal is replaced by a component that is electrically conductive enough without being an EMC seal strictly speaking according to the generally accepted meaning in the field.

Optionally, as illustrated in FIGS. 2 and 3, at least one clip 52 associated with a screen 80 coming into contact with or near the clip 52 comprises an electromagnetic insulation cover 94 extending forward toward the connector holder 16, so that the screen 80 and the cover 94 extend on either side of the conductors 58 of the associated cable 50. The clip 52, the screen 80 and the connector holder 16 delimit a box around the conductors 58 protecting the latter from electromagnetic disruptions.

During operation, the insertion of each daughter board 8 in its site E1, E2, E3 in the drawer 6 causes the connection of the associated drawer connector. The insertion of the drawer 6 equipped with daughter boards 8 causes the compartment connectors 40 to be plugged in. When the drawer 6 equipped with the daughter boards 8 is inserted into the compartment 4 (FIG. 3), each screen 80 extends along an associated compartment connector 40 and protects it from electromagnetic disruptions.

Advantageously, and as is the case in the illustrated embodiment, each screen 80 extends between two adjacent compartment connectors 40 while physically separating them, i.e. forming a separating partition between them in the bottom of the compartment 4 when the drawer 6 equipped with the boards 8 is inserted into the compartment 4 (FIG. 3). Each screen 80 delimits, inside the compartment 4, two separate compartments, one for each of the compartment connectors 40 between which it extends. Thus, this screen also plays the role of a partition that physically separates the different types of electromagnetic waves coming from the electrical signals circulating in the wires connected to the connector on either side of said partition.

In the illustrated example, each screen 80 extends substantially over the entire internal height of the compartment 4 (FIG. 1) considered in a transverse direction to ensure an effective separation. As illustrated in FIG. 1, the stationary part 82 of each screen 80 extends substantially over the entire height of the cable housing delimited at the back of the connector holder 16 by the edge 54 of the connector holder 16 and the mobile part 84 of each partition 80 extends substantially over the entire height of the drawer housing 12 defined by the drawer holder 10.

The screen 80 being electrically conductive and electrically connected on the one hand to the connector holder 16, and thus to the drawer holder 10, and, on the other hand, to the electrical mass of a daughter board 8 or to the drawer 6, defines protection against electromagnetic disruptions coming from other compartment connectors 40 and from the outside.

Owing to the invention, it is possible to use low-cost compartment connectors, for example according to standard F48 (DIN41612), adapted to easy blind connections, while effectively protecting the compartment connectors 40 from electromagnetic disruptions coming from other compartment connectors 40 and from the outside.

The two-part screens 80 (stationary part 82 and mobile part 84) make it possible to provide a part protecting the first part of the compartment connector and its associated connector (cable 50 and its conductors 58) and a part protecting the second part of the compartment connector 40.

The invention is not limited to the embodiment described in reference to FIGS. 1 to 3.

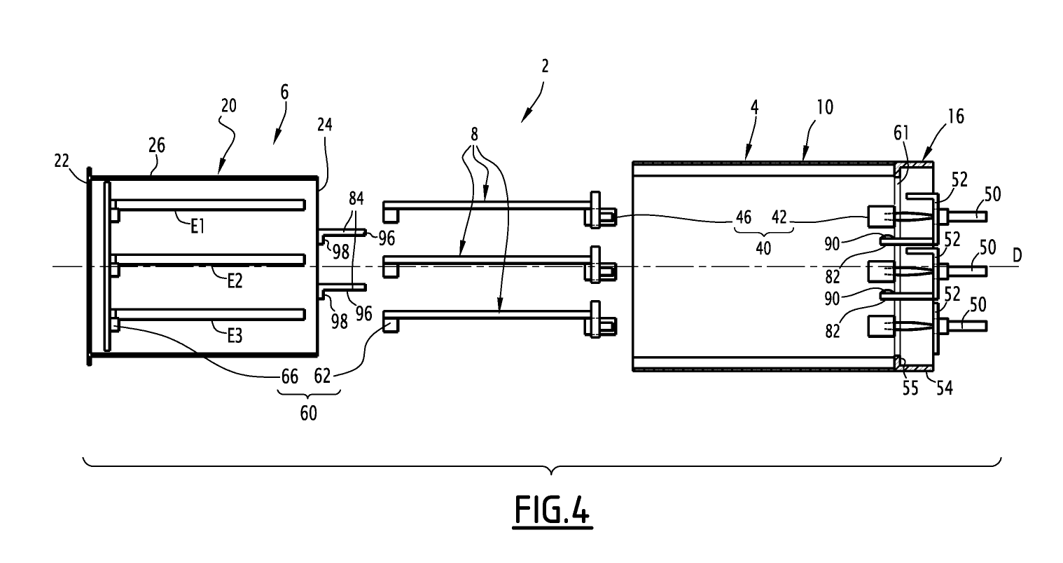

The embodiment of FIGS. 4 and 5 differs from that of FIGS. 1 to 3 in that the mobile parts 84 are fastened on the back surface of the drawer 6 instead of being fastened on the daughter boards 8.

Each mobile part 84 comprises a protective portion 96 intended to form a protective screen and a fastening portion 98 forming an angle between them. The protective portion and the portion define an “L” shape. The base of the “L” shape is made up of the fastening portion 98, and the ascender by the protective portion 96. Alternatively, it is possible to provide a generally T-shaped mobile part 84. In that case, the protective portion defines the ascender and the fastening portion defines the bar of the “T” shape.

In this embodiment, the two-part screens 80 (stationary part 82 and mobile part 84) provided on the drawer 6 and the compartment 4 are put in place even in the absence of an associated daughter board 8.

Other embodiments or alternatives are also possible.

It is thus possible to combine the embodiment of FIGS. 1 to 3 with that of FIGS. 4 and 5 by providing mobile screen parts fastened on boards and mobile screen parts fastened on the drawer.

In one possible alternative, one or several electromagnetic protective screen(s) is (are) provided in a single part. This part can be provided stationary and fastened on the compartment or mobile and fastened on a board or on the drawer. If it is fastened on the compartment, it comes into electrical contact with the drawer during its insertion into the compartment or in electrical contact with a conductive portion of the board connected to the mass of said board. If it is fastened on the board or the drawer, it comes into electrical contact with the compartment during the insertion of the drawer into the compartment.

In general, screens made up of one part or screen parts made up of several parts can be provided on the compartment and/or the drawer to protect compartment connectors associated with boards lacking screens or screen parts or provided with screen parts.

In this way, the invention generally relates to an electronic assembly comprising the compartment and the drawer, whether or not it is pre-equipped with boards. It of course also relates to electronic assemblies comprising a compartment, a drawer and boards.

Furthermore, it is possible to provide a limited number of screens, situated only on either side of the compartment connectors requiring a high electromagnetic immunity, due to the connector type. The compartment connectors producing network connections for transmitting signals encoding data, of the Ethernet type, generally require increased electromagnetic protection. It is for example possible to protect the data transmission compartment connectors from the power transmission compartment connectors.

It is also possible to provide a screen associated with an end compartment connector, so that the screen does not extend between two compartment connectors. For example, in the embodiments of FIGS. 1 to 3 and 4 and 5, an additional screen could be associated with the compartment connector 40 situated at the bottom of FIGS. 1 and 3, 4 and 5, to protect it from outside disruptions.

It is also possible to provide additional covers only for the compartment connectors requiring high electromagnetic protection.

Furthermore, in the embodiments of FIGS. 1 to 3 and 4 and 5, the drawer connectors and the compartment connectors are arranged on the opposite front and back edges of the boards.

In another possible embodiment corresponding to an electronic assembly similar to that disclosed in patent EP 1 732 374, the first parts of the drawer connectors and the compartment connectors are arranged on the same back edge of the daughter boards, so that each daughter board can be inserted into the drawer being beforehand inserted into the compartment, the insertion of the daughter board 8 being done in the longitudinal direction D from front to back while simultaneously pinning the first and second parts of the drawer connector and the first and second part of the compartment connector in the longitudinal direction D, and in the same direction.

The invention applies to many fields, in particular the transportation field, including the railroad field, irrespective of whether the electronic assembly is onboard.

1. An electronic assembly comprising:
a drawer comprising sites for receiving boards that can be removably inserted into the drawer;
a compartment comprising a drawer holder having an insertion opening at the front of the drawer holder and a connector holder at the rear of the drawer holder, the drawer being able to be removably inserted into the drawer holder from front to back, in a longitudinal direction;
a first compartment connector part associated with each board site, wherein the first compartment connector part is fastened on the connector holder and is provided to be plugged in with a second compartment connector part fastened on a board due to the insertion of the drawer equipped with the board into the drawer holder;
at least one electromagnetic protection screen provided to be adjacent to a first compartment connector part and able to produce an electrical connection between the drawer holder or the connector holder and a board arranged in the site associated with the first compartment connector part when the drawer is inserted into the compartment.

2. The electronic assembly according to claim 1, wherein the screen extends backward and/or forward from the connector holder relative to the longitudinal direction.

3. The electronic assembly according to claim 1, wherein the screen is configured to physically separate two first adjacent compartment connector parts by defining a separating partition between them in the bottom of the compartment.

4. The electronic assembly according to claim 1, wherein the screen comprises at least one stationary part fastened on the connector holder.

5. The electronic assembly according to claim 4, wherein the screen comprises at least one mobile part fastened on a board or on the drawer.

6. The electronic assembly according to claim 5, wherein the stationary part and the mobile part are complementary and connect electrically upon insertion of the drawer equipped with the boards into the compartment to form the screen.

7. The electronic assembly according to claim 6, further comprising an electromagnetic continuity seal arranged so that the stationary part and the mobile part connect electrically via said electromagnetic continuity seal.

8. The electronic assembly according to claim 7, wherein the electromagnetic continuity seal is arranged on the stationary part or on the mobile part.

9. The electronic assembly according to claim 1, wherein the screen comprises:
a protective portion provided to extend along a compartment connector; and
a portion for fastening the protective portion, the portion for fastening the protective portion and the protective portion together forming an angle of about 90°.

10. The electronic assembly according to claim 9, wherein the protective portion and the fastening portion together define a “T” or “L” shape.

11. The electronic assembly according to claim 1, wherein the screen comprises a substantially planar plate.

12. The electronic assembly according to claim 1, wherein the screen extends substantially over the entire internal height of the compartment in a transverse direction.

13. The electronic assembly according to claim 1, further comprising at least one shielded cable fastened on the connector holder via a mounting and take-up shielding clip.

14. The electronic assembly according to claim 13, wherein the mounting and take-up shielding clip comprises an electromagnetic insulation cover extending forward toward the connector holder, in the longitudinal direction such that the screen and the cover extend on either side of the associated cable.

15. The electronic assembly according to claim 1, further comprising at least one board that can be inserted into a site of the drawer and that comprises a second compartment connector part complementary to the first compartment connector part associated with the site.

16. A board for producing an electronic assembly according to claim 5, comprising a second compartment connector part complementary with a first compartment connector part associated with a site of the drawer, and at least one mobile electromagnetic protective screen part adjacent to the second compartment connector part.

17. A use of an electronic assembly according to claim 1 to connect a board.
